(19) United States
(12) Patent Application Publication
(10) Pub. No.: US 2004/0105194 A1
(43) Pub. Date: Jun. 3, 2004

(54) Spin valve transistor with stabilization and method for producing the same

(76) Inventors: Robert E. Fontana JR., San Jose, CA (US); Jeffrey S. Lille, Sunnyvale, CA (US)

Correspondence Address: FREDERICK W. GIBB, III, MCGINN & GIBB, PLLC, 2568-A RIVA ROAD, SUITE 304, ANNAPOLIS, MD, 21401, US

(21) Appl. No.: 10/307,062

(22) Filed: Nov. 29, 2002

(51) Int. Cl. G11B 5/39; H01L 29/82

(52) U.S. Cl. 360/324.12; 257/421

(57) ABSTRACT

A method and structure for a spin valve transistor (SVT) comprises a magnetic field sensor, a first insulating layer adjacent the magnetic field sensor, a bias layer adjacent the insulating layer, a second insulating layer adjacent the bias layer, and a ferromagnetic layer over the second insulating layer, wherein the first insulating layer and the second insulating layer comprise antiferromagnetic materials. The magnetic field sensor comprises a base region, a collector region adjacent the base region, an emitter region adjacent the base region, and a barrier region located between the base region and the emitter region. The bias layer is between the first insulating layer and the second insulating layer. The bias layer is magnetic and is at least three times the thickness of the base region.

### BACKGROUND OF THE INVENTION

1. Field of the Invention

The present invention generally relates to magnetoelectronic devices, and more particularly to a spin valve transistor (SVT) having an insulating hard bias stabilization.

2. Description of the Related Art

A spin valve transistor is a vertical spin injection device which has spin oriented electrons injected over a barrier into a free layer, and is used as a magnetic field sensor device. Those spin oriented electrons that are not spin scattered continue and then traverse a second barrier. The current over the second barrier is referred to as the magneto-current. Conventional devices are constructed using silicon wafer bonding to define the barriers.

Conventional spin valve transistors are constructed using a traditional three-terminal framework having an emitter/base/collector structure of a bipolar transistor. SVTs further include a spin valve on a metallic base region, whereby the collector current is controlled by the magnetic state of the base using spin-dependent scattering.

A conventional SVT is described by Jansen, R. et al., Journal of Applied Physics, Vol. 89, No. 11, June 2001, “The spin-valve transistor: Fabrication, characterization, and physics.” FIG. 1 illustrates a conventional SVT having a semiconductor emitter region, a collector region, and a base region which contains a metallic spin valve. The semiconductors and magnetic materials used may include an n-type Si as an emitter and collector, and a Ni₈₀Fe₂₀/Au/Co spin valve in the base region. Energy barriers, also referred to as Schottky barriers are formed at the junctions between the metal base and the semiconductors. It is desirable to obtain a high quality energy barrier at these junctions having good rectifying behavior, therefore, thin layers of magnetic materials, such as Pt and Au, are used at the emitter and collector regions, respectively. Moreover, these thin layers separate the magnetic layers from the semiconductor materials.

A conventional SVT functions when a current is introduced between the emitter region and the base region (denoted as I_{E} in FIG. 1). This occurs when electrons are injected over the energy barrier and into the base region, such that the electrons are perpendicular to the layers of the spin valve. Moreover, because the electrons are injected over the energy barrier, they enter the base region as non-equilibrium hot electrons, whereby the hot-electron energy is typically in the range of 0.5 and 1.0 eV depending upon the selection of the metal/semiconductor combination.

The energy and momentum distribution of the hot electrons change as the electrons move through the base region and are subjected to inelastic and elastic scattering. As such, electrons are prevented from entering the collector region if their energy is insufficient to overcome the energy barrier at the collector side. Moreover, the hot-electron momentum must match with the available states in the collector semiconductor to allow for the electrons to enter the collector region.

The collector current I_{C}, which indicates the fraction of electrons that is collected in the collector region is dependent upon the scattering in the base region, which is spin dependent when the base region contains magnetic materials. Furthermore, an external applied magnetic field controls the total scattering rate, which may, for example, change the relative magnetic alignment of the two ferromagnetic layers of the spin valve. The magnetocurrent (MC), which is the magnetic response of the SVT can be represented by the change in collector current normalized to the minimum value as provided by the following formula: MC=[I^{P}_{C}−I^{AP}_{C]/I}^{AP}_{C}, where P and AP indicate the parallel and antiparallel state of the spin valve, respectively.

The drawbacks of the conventional devices are that the emitter region is not amply electrically isolated from the base layer (free layer). This causes the free layer to “wander”, wherein the magnetization of the free layer is not oriented in a proper position resulting in an unstable device. Therefore, there is a need for a novel spin valve transistor which overcomes the limitations of the conventional devices.

### SUMMARY OF THE INVENTION

The present invention has been devised to provide a structure and method for a structure and method compatible with sub-micron lithography to produce a spin valve transistor having an insulating hard bias stabilization. The present invention provides a spin valve transistor having a stable free layer in a highly sensitive read device. The present invention provides a spin valve transistor which has a read head in a shielded environment. The present invention provides a magnetic field sensor device having an insulating hard bias stabilization layer that is adjacent to the sensor having a track width and stripe height defined by separate lithography steps.

There is provided, according to one aspect of the invention, a spin valve transistor (SVT) comprising a magnetic field sensor, a first insulating layer adjacent the magnetic field sensor, a bias layer adjacent the insulating layer, a second insulating layer adjacent the bias layer, and a ferromagnetic layer over the second insulating layer, wherein the first insulating layer and the second insulating layer comprise antiferromagnetic materials. The magnetic field sensor comprises a base region, a collector region adjacent the base region, an emitter region adjacent the base region, and a barrier region located between the base region and the emitter region. The bias layer is between the first insulating layer and the second insulating layer. The bias layer is magnetic and is at least three times the thickness of the base region.

The present invention further provides a method of manufacturing a spin valve transistor, wherein the method comprises placing an antiferromagnetic insulating layer adjacent a magnetic field sensor, positioning a magnetic hard bias layer adjacent the insulating layer, and laying a second insulating layer adjacent the bias layer. The magnetic field sensor comprises a base region, a collector region adjacent the base region, an emitter region adjacent the base region, and a barrier region located between the base region and the emitter region. The hard bias layer is positioned between the insulating layer and the second insulating layer. The method further comprises placing a ferromagnetic layer over the second insulating layer.

The advantages of the present invention are several. First, the present invention can stabilize a free layer in a highly sensitive read head device. Also, the present invention can create a read head in a shielded environment. Moreover, the present invention provides a spin valve transistor with insulating hard bias stabilization that is adjacent to a magnetic field sensor, wherein the sensor has its track width and stripe height defined by separate lithography steps. The present invention further has a magnetic shield that covers the sensor device in an asymmetric shape relative to the plane of the deposited end of the substrate, thereby stabilizing the device.

### BRIEF DESCRIPTION OF THE DRAWINGS

The invention will be better understood from the following detailed description of a preferred embodiment(s) of the invention with reference to the drawings, in which:

FIG. 1 is a schematic diagram of a conventional spin valve transistor device;

FIG. 2 is a cross-sectional diagram of a spin valve transistor device according to the present invention;

FIG. 3 is a cross-sectional diagram of a spin valve transistor device according to the present invention;

FIG. 4 is a cross-sectional diagram of a spin valve transistor device according to the present invention;

FIG. 5 is a cross-sectional diagram of a spin valve transistor device according to the present invention;

FIG. 6 is a cross-sectional diagram of a spin valve transistor device according to the present invention;

FIG. 7 is a cross-sectional diagram of a spin valve transistor device according to the present invention;

FIG. 8 is a flow diagram illustrating a preferred method of the invention;

FIG. 9 is a perspective view of a spin valve transistor device according to the present invention;

FIG. 10 is a cross-sectional diagram of a spin valve transistor device according to the present invention;

FIG. 11 is a cross-sectional diagram of a spin valve transistor device according to the present invention;

FIG. 12(a) is a cross-sectional diagram of a spin valve transistor device according to the present invention;

FIG. 12(b) is a top plan view of a spin valve transistor device according to the present invention;

FIG. 13(a) is a cross-sectional diagram of a spin valve transistor device according to the present invention;

FIG. 13(b) is a top plan view of a spin valve transistor device according to the present invention;

FIG. 14(a) is a cross-sectional diagram of a spin valve transistor device according to the present invention;

FIG. 14(b) is a top plan view of a spin valve transistor device according to the present invention;

FIG. 15(a) is a cross-sectional diagram of a spin valve transistor device according to the present invention;

FIG. 15(b) is a top plan view of a spin valve transistor device according to the present invention;

FIG. 16(a) is a cross-sectional diagram of a spin valve transistor device according to the present invention;

FIG. 16(b) is a top plan view of a spin valve transistor device according to the present invention;

FIG. 17(a) is a cross-sectional diagram of a spin valve transistor device according to the present invention;

FIG. 17(b) is a top plan view of a spin valve transistor device according to the present invention;

FIG. 18(a) is a cross-sectional diagram of a spin valve transistor device according to the present invention;

FIG. 18(b) is a top plan view of a spin valve transistor device according to the present invention;

FIG. 19(a) is a cross-sectional diagram of a spin valve transistor device according to the present invention;

FIG. 19(b) is a top plan view of a spin valve transistor device according to the present invention;

FIG. 20(a) is a cross-sectional diagram of a spin valve transistor device according to the present invention; and

FIG. 20(b) is a top plan view of a spin valve transistor device according to the present invention.

### DETAILED DESCRIPTION OF PREFERRED EMBODIMENTS OF THE INVENTION

As previously mentioned, there is a need for a novel spin valve transistor device having insulating hard bias stabilization. Referring now to the drawings, and more particularly to FIGS. 2 through 9, there are shown preferred embodiments of the method and structures according to the present invention, in which there is provided a spin valve transistor 1 comprising a magnetic field sensor 3, an insulating layer 25 adjacent to the magnetic field sensor 3, and a hard bias layer 30 adjacent to the insulating layer 25.

The processing steps involved in manufacturing the are sequentially illustrated in FIGS. 2 through 8, wherein there is shown in FIG. 2 a magnetic field sensor 3 comprising a base region 15, a collector region 20 adjacent the base region 15, an emitter region 5 adjacent the base region 15, and a barrier region 10 located between the base region 15 and the emitter region 5. A resist layer 8 is further shown adjacent the metal emitter 5, which defines the track width of the sensor 3.

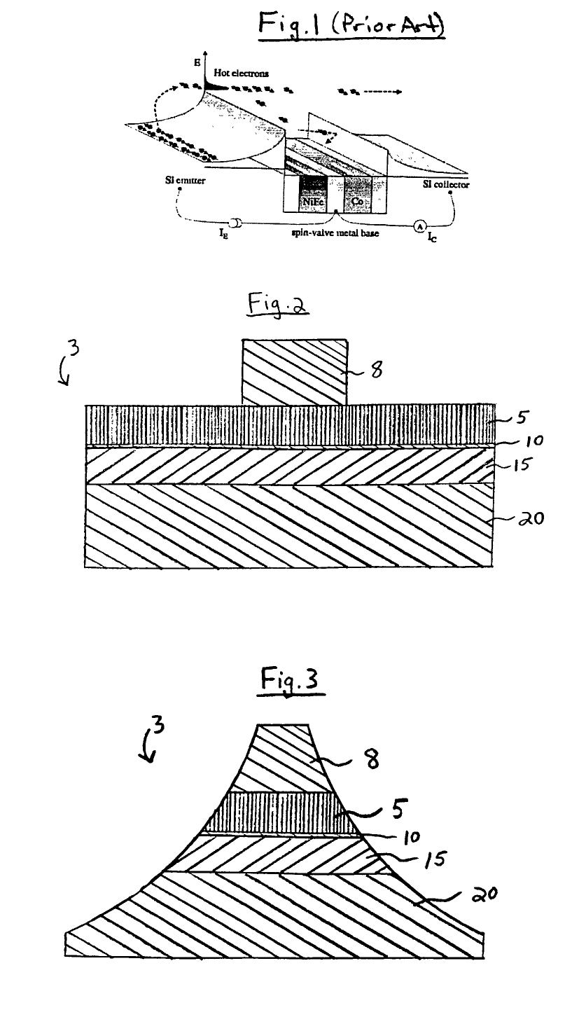

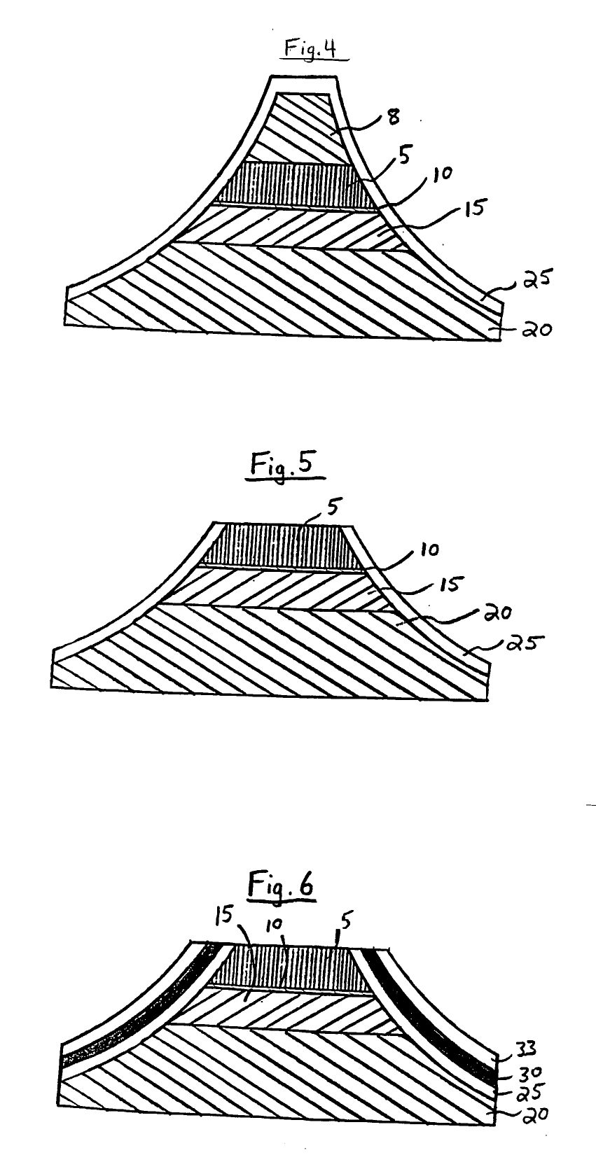

As seen in FIG. 3, the device 3 is defined by milling at various mill angles for sensor sidewall definition. Then, as illustrated in FIG. 4, the insulator 25 is deposited around the remaining sensor 3. The insulator 25 comprises an antiferromagnetic material, such as NiO or alumina and is operable to electrically isolate the emitter 5 from the free layer (base) 15.

The magnetic field sensor 3 allows hot electrons emitted from the emitter 5 to travel through to the free layer 15, and to reach the collector 20, which collects the magnetocurrent (collects the electrons). The free layer 15 preferably comprises a soft ferromagnetic material such as NiFe, CoFe, Si, Cu, TB₂. In operation, the device 3 acts as a hot spin electron filter, whereby the barrier 10 between the emitter 5 and the free layer 15 operates to selectively allow the hot electrons to pass on through to the free layer 15, and then on through to the collector 20. The barrier layer 10 is preferably comprised of aluminum oxide, and is generally less than ten angstroms in thickness.

Next, as best seen in FIG. 5, the resist 8 is either removed via a liftoff process or chemical mechanical polish (CMP) assisted liftoff to break the sidewall redeposition of metal on the side of the resist to allow a solvent to clean to the entire surface of the wafer 3. At the air bearing surface (ABS), the sensor 3 would have insulation via the antiferromagnetic layer 25 adjacent to the sensor 3.

FIG. 6 shows the next step in the processing, whereby a hard bias magnetic layer 30 is deposited adjacent to the insulator layer 25. Then, a second antiferromagnetic insulating layer 33, preferably comprising alumina, is deposited adjacent the hard bias layer 30, wherein the hard bias layer 30 is sandwiched between the insulating layer 25 and the second insulating layer 33. The thickness of the hard bias layer 30 serves to stabilize the device 3, and moreover, allows the magnetization of the free layer 15 to point towards the hard bias layer 30, that is parallel to the ABS plane. Thus, when the spin valve transistor 1 is not functioning, the device 3 is in a known state (magnetization of the free layer 15 is parallel to the ABS plane). This is advantageous over conventional devices because the free layer 15 is prevented from wandering, and in fact, is positioned (magnetization is pointed) in the correct position, as further explained below.

The scattering of electrons within the free layer 15 is dependent upon the orientation of the magnetization within the free layer 15. For example, if the magnetization is pointing upwards in the free layer 15 (parallel to the ABS plane), as provided by the present invention, then the electrons are not scattered as much and the device 3 is in a known state. However, if the magnetization is pointing downwards, as with conventional devices, then there is little stability with regard to the magnetic field sensor. Therefore, the hard bias layer 30 of the present invention stabilizes the sensor 3.

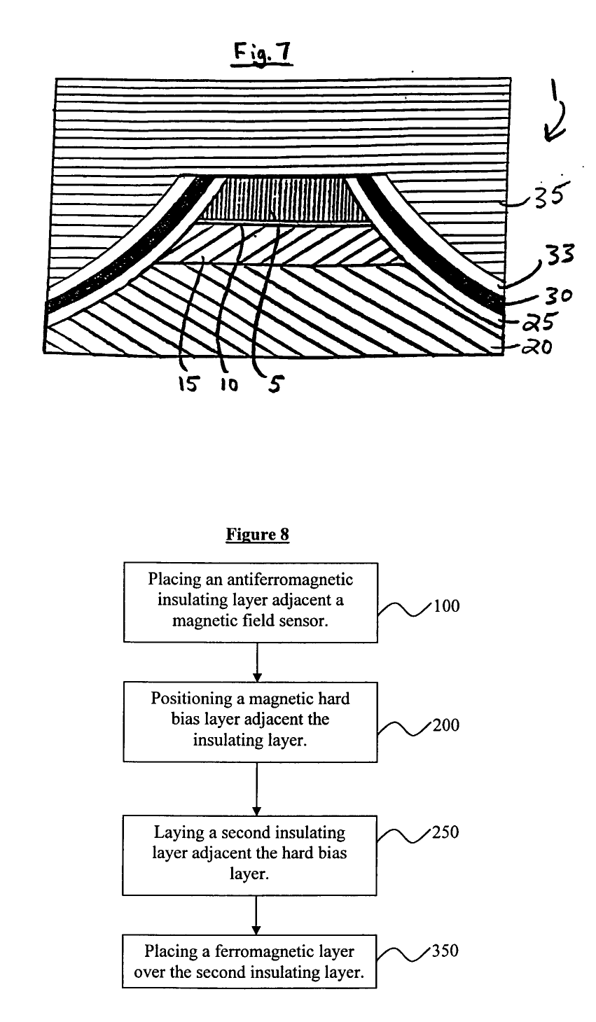

Next, in a preferred embodiment illustrated in FIG. 7, a ferromagnetic layer 35 is deposited over the hard bias layer 30 and acts as a shield 35 to the sensor 3. After this, a ferromagnetic shield 35 is deposited over the second insulating layer 33. The ferromagnetic shield 35 covers a majority of the sensor 3 including parts of the sides to minimize side reading. Moreover, the shield 35 also acts as the electrical connection for the emitter 5. The shield 35 does not channel magnetization, but still allows for an electrical connection to occur. Moreover, the shield 35 provides a connection to an external lead (not shown).

The thickness of the hard bias layer 30 is a factor with regard to pinning strength. Pinning strength relates to the relative freedom with which the electrons move in the free layer. The hard bias layer 30 cannot be too thick because this would increase the space between the shield 35 and the free layer 15, which would essentially pin the free layer 15 preventing it from flipping freely. Likewise, a hard bias layer 30, which is too thin results in not enough pinning strength, causing an unstable sensor 3.

Similarly, an insulator 25 or second insulating layer 33, which is too thick also increases the spacing between the free layer 15 and the shield 35, thereby effecting the pinning strength. Thus, preferably the hard bias layer 30 is approximately at least three times the thickness of the base region 15 (and preferably four times the thickness of the base region 15), wherein the base region 15 is approximately 30-40 angstroms, the hard bias layer 30 is approximately 120-160 angstroms, and the insulator 25 is approximately 100-800 angstroms in thickness.

A preferred method of manufacturing a spin valve transistor 1 is illustrated in the flow diagram of FIG. 8, wherein the method comprises placing 100 an antiferromagnetic insulating layer 25 adjacent a magnetic field sensor 3, and positioning 200 a magnetic hard bias layer 30 adjacent the insulating layer 25, wherein the magnetic field sensor 3 comprises a base region 15, a collector region 20 adjacent the base region 15, an emitter region 5 adjacent the base region 15, and a barrier region 10 located between the base region 15 and the emitter region 5. The method further comprises laying 250 a second insulating layer 33 adjacent the hard bias layer 30, and placing 350 a ferromagnetic layer 35 over the second insulating layer 33.

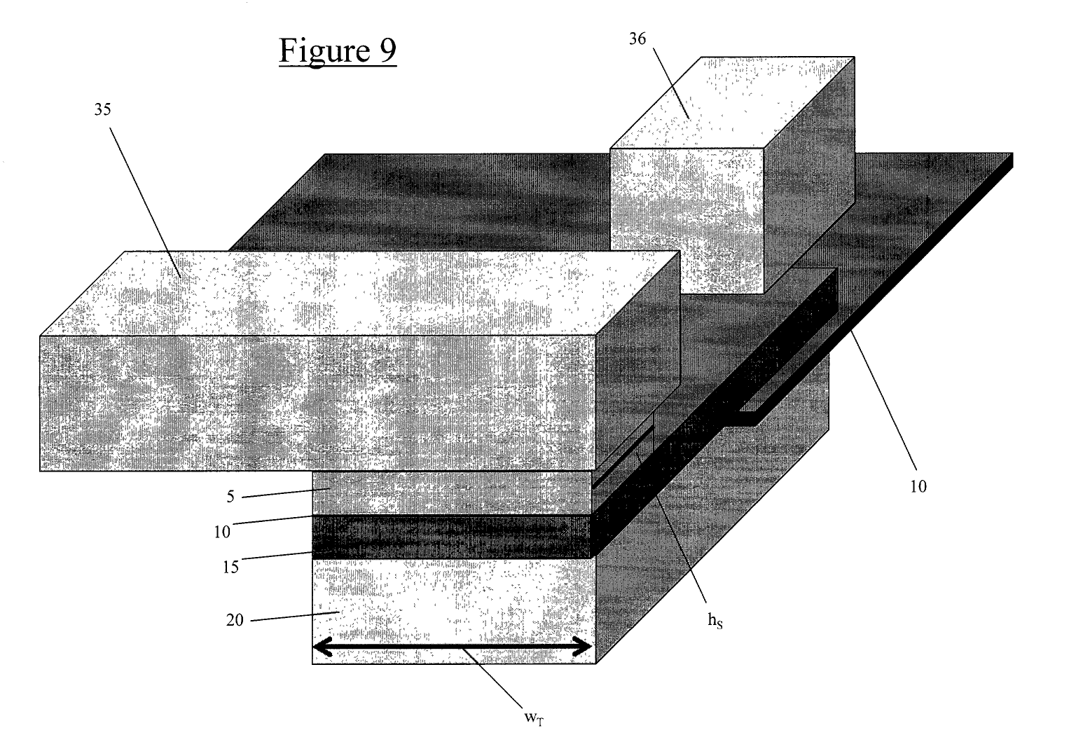

A perspective view of a current tunnel transistor, embodied as a spin valve transistor, according to an embodiment of the invention is illustrated in FIG. 9. In this view, the current tunnel transistor is shown without a hard bias layer 30. As indicated the current tunnel transistor comprises a collector substrate 20, preferably comprising silicon, with an oxide barrier layer 10 disposed thereon. Above the barrier layer 10 is a base layer (free layer) 15. Another tunnel barrier layer 10 is configured over the base layer 15, wherein this tunnel barrier layer 10 creates a separation between the base layer 15 and the emitter (top lead) 5. A lead connection 35, which may be embodied as a ferromagnetic shield 35 is positioned over the emitter region 5. A base lead 36 is positioned over the base 15. As indicated, the stripe height hs is defined by the dimensions of the emitter 5, while the track width WT is defined by the dimensions of the emitter 5, base 15, and collector 20.

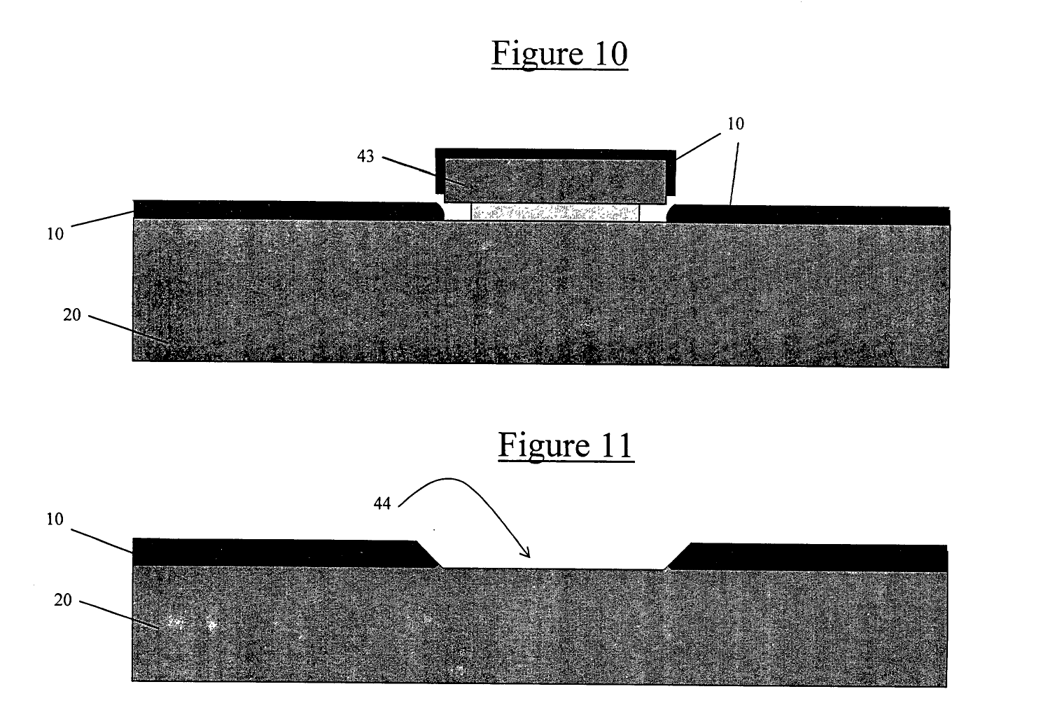

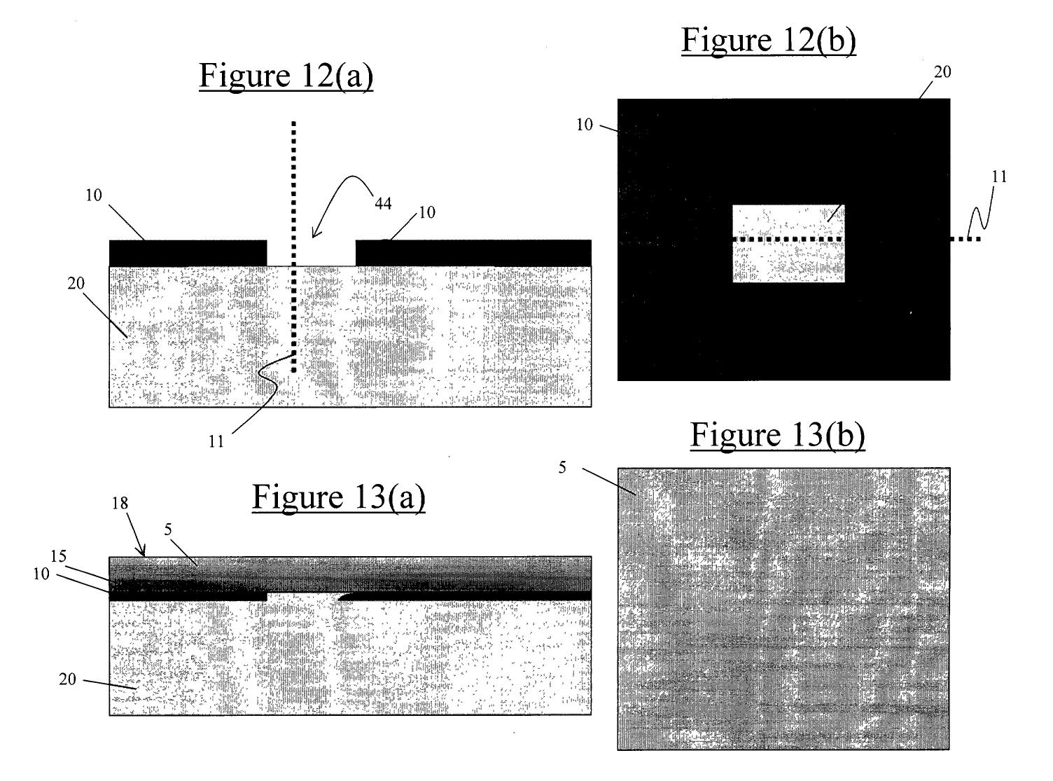

The spin valve transistor is manufactured using several lithographic steps. In FIG. 10, the collector substrate 20 is shown with the insulating oxide barrier 10 disposed thereon. A resist pattern 43 is used to remove a portion of the oxide barrier 10, which creates a via 44 down to the semiconductor substrate 20, which is shown in FIG. 11. The removal of the oxide barrier 10 may be performed using conventional etching techniques. The air bearing surface of the resulting sensor structure is represented by a dotted line 11 in FIGS. 12(a) and 12(b) as well as in the subsequent drawings.

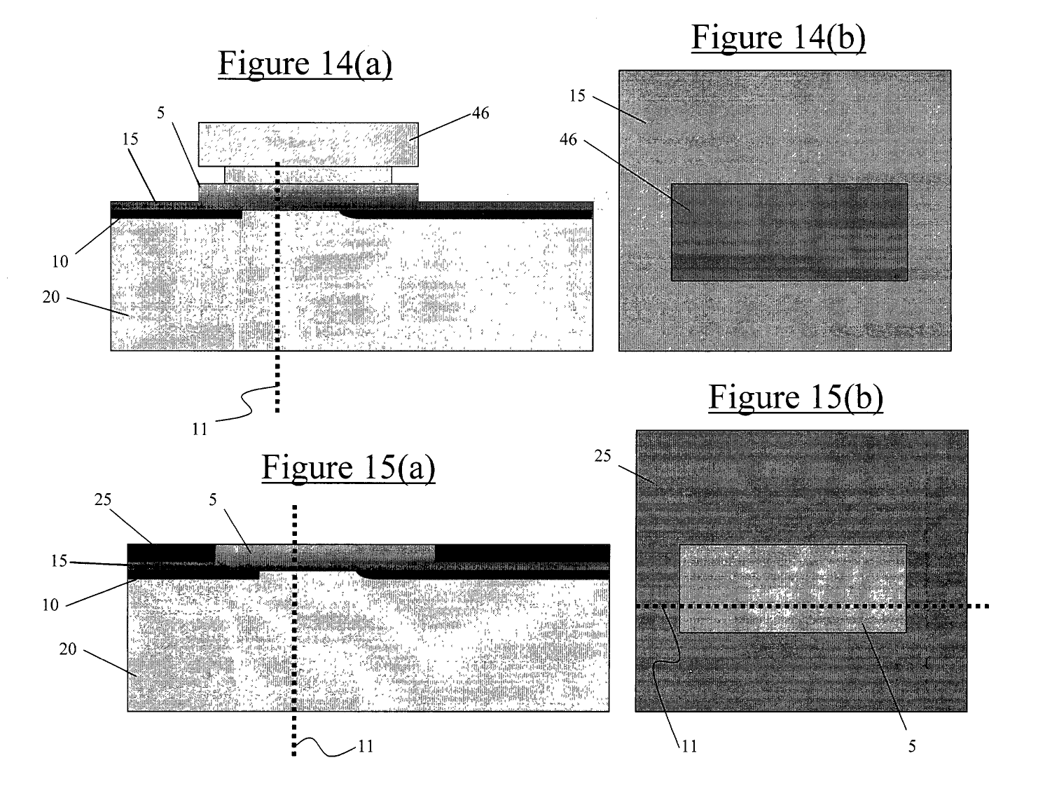

In FIG. 13(a) a sensor stack 18 is placed over the insulating barrier 10 and into the via 44. The sensor stack 18 comprises the emitter region 5 positioned over the base layer 15. The top plan view of FIG. 13(b) illustrates the upper cap of the sensor stack 18, which is actually the emitter surface 5. Next, as depicted in FIGS. 14(a) and 14(b), another resist 46 is used to pattern the sensor stack 18, where portions of the emitter region 5 are removed using known techniques such as ion milling or reactive ion etching. This exposes the base layer 15 and defines the stripe height hs of the device. Thereafter, as shown in FIGS. 15(a) and 15(b), an insulator 25, such as alumina, is filled in the areas over the exposed base layer 15.

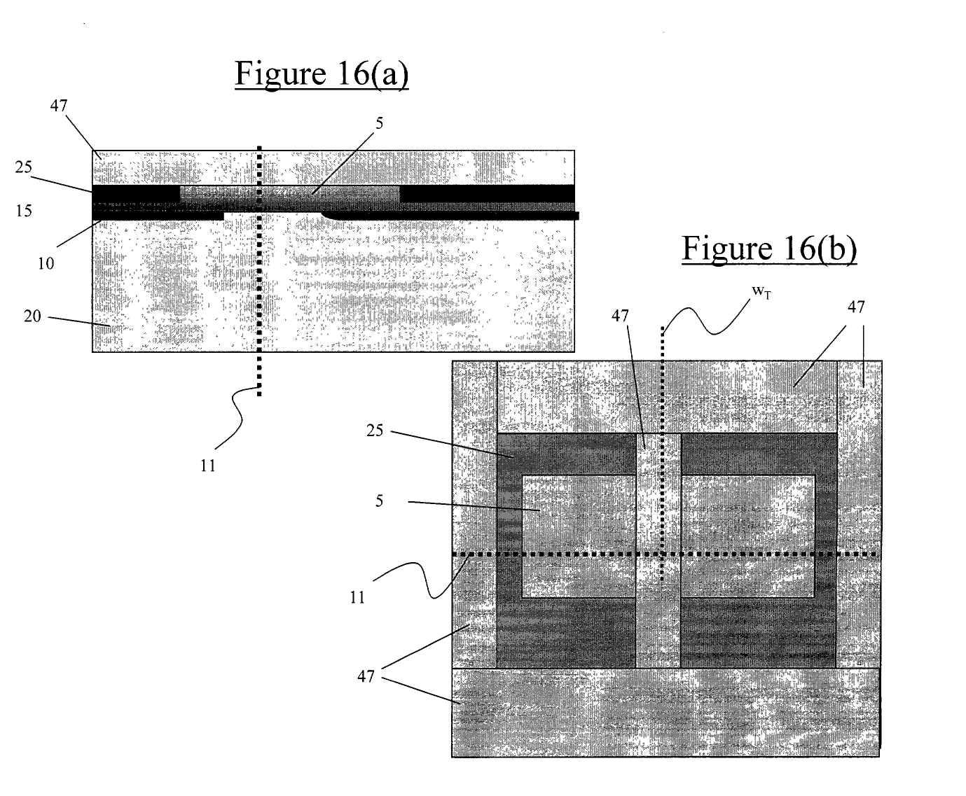

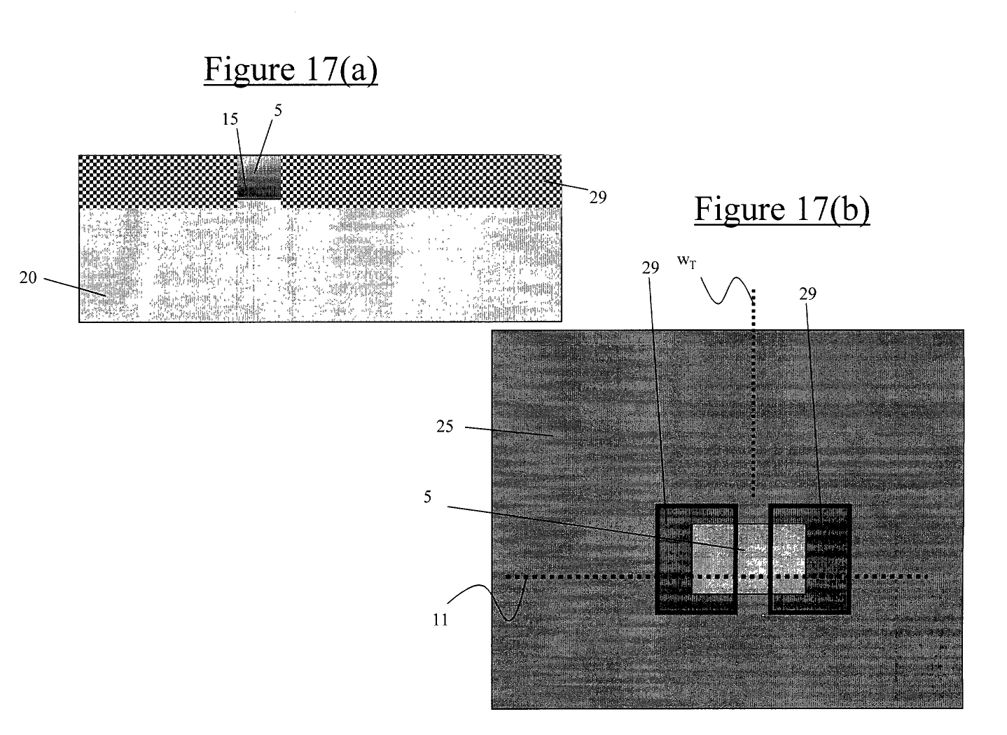

In the next stage of processing illustrated in FIGS. 16(a) and 16(b), a resist 47 is used to pattern the transistor device along the track width location WT of the device. The resist pattern 47 is best seen in FIG. 16(b) along with exposed portions of the insulator 25 and emitter 5. After the resist 47 is removed a hard bias layer 30 and second insulator layer 33 are deposited over the first insulator layer 25. Collectively, the first insulator 25, hard bias layer 30, and second insulator layer 33 form a stack 29, which is seen in FIG. 17(a), which illustrates the device in the ABS plane, and FIG. 17(b), which illustrates a top plan view of the device.

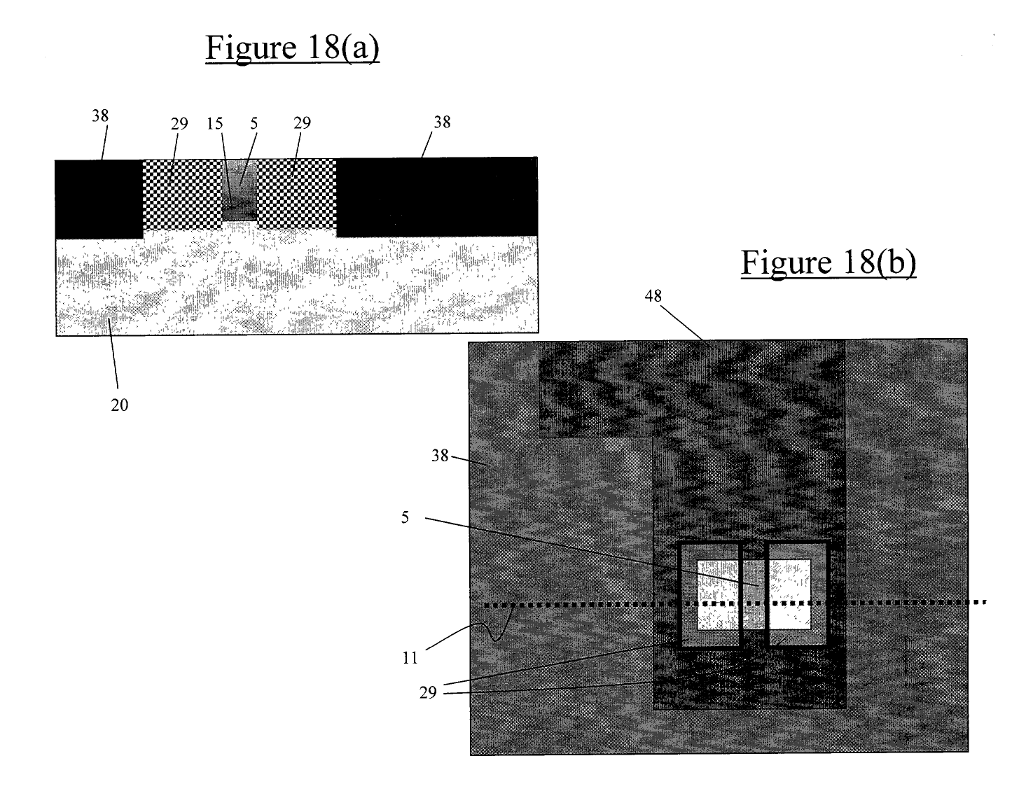

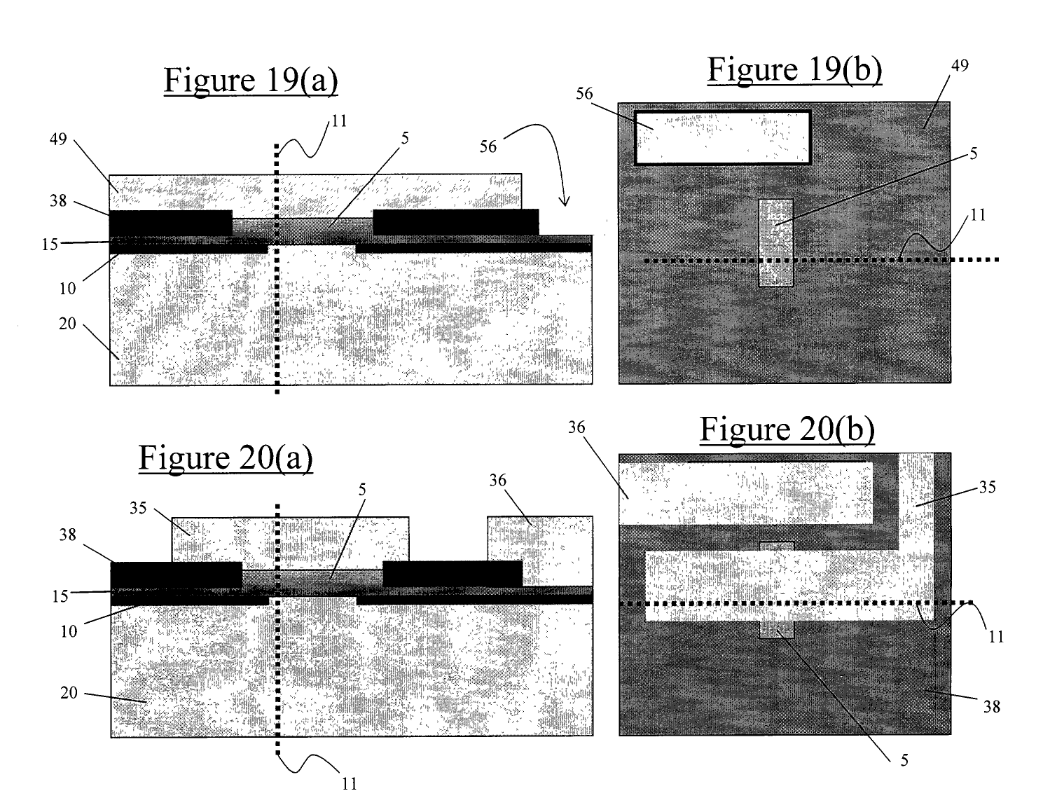

In FIGS. 18(a) (viewed in the ABS plane) and 18(b) portions of the stack 29 are removed, and the device is configured such that the only portion of the emitter 5 and base 15 remaining is located between the insulator/bias/insulator stack 29. A resist 48 is used to pattern the device and an insulator 38 fills the exposed portions of the device. FIGS. 19(a) and 19(b) illustrate the device with a resist 49 used to pattern a via 56 to the base layer 15 and a via (not shown) to the collector 20. Thereafter, after patterning is completed, the transistor device is plated with a top lead 35 and base lead 36, wherein both leads 35, 36 preferably comprise NiFe. Other leads, such as the collector lead (not shown) are also included.

The advantages of the present invention are several. First, the present invention can stabilize a free layer 15 in a highly sensitive read head device 1. Also, the present invention can create a read head in a shielded environment. Moreover, the present invention provides a spin valve transistor 1 with insulating hard bias stabilization that is adjacent to a magnetic field sensor 3, wherein the sensor 3 has its track width and stripe height defined by separate lithography steps. The present invention also has three separate output connection pads 45 on top of the slider body 40. The present invention further has a magnetic shield 35 that covers the sensor device 3 in an asymmetric shape relative to the plane of the deposited end of the substrate, thereby stabilizing the device 3.

While the invention has been described in terms of preferred embodiments, those skilled in the art will recognize that the invention can be practiced with modification within the spirit and scope of the appended claims.

What is claimed is:

1. A spin valve transistor comprising:
a magnetic field sensor;
a first insulating layer adjacent said magnetic field sensor;
a bias layer adjacent said insulating layer; and
a second insulating layer adjacent said bias layer.

2. The spin valve transistor of claim 1, wherein said magnetic field sensor comprises:
a base region;
a collector region adjacent said base region;
an emitter region adjacent said base region; and
a barrier region located between said base region and said emitter region.

3. The spin valve transistor of claim 1, wherein said bias layer is between said first insulating layer and said second insulating layer.

4. The spin valve transistor of claim 1, further comprising a ferromagnetic layer over said second insulating layer.

5. The spin valve transistor of claim 2, wherein said bias layer is magnetic and is at least three times the thickness of said base region.

6. The spin valve transistor of claim 1, wherein said first insulating layer and said second insulating layer comprise antiferromagnetic materials.

7. A spin valve transistor comprising:
a magnetic field sensor;
an antiferromagnetic insulator surrounding said magnetic field sensor;
a magnetic bias layer adjacent said insulator;
a second insulator adjacent said magnetic bias layer; and
a ferromagnetic layer over said magnetic bias layer.

8. The spin valve transistor of claim 7, wherein said magnetic field sensor comprises:
a base;
a collector adjacent said base;
an emitter adjacent said base; and
a barrier region located between said base and said emitter.

9. The spin valve transistor of claim 7, wherein said magnetic bias layer is between said insulator and said second insulator.

10. The spin valve transistor of claim 7, wherein said second insulator is between said ferromagnetic layer and said magnetic bias layer.

11. The spin valve transistor of claim 8, wherein said magnetic bias layer is at least three times the thickness of said base.

12. The spin valve transistor of claim 7, wherein said second insulating layer comprises antiferromagnetic material.

13. A method of manufacturing a spin valve transistor, said method comprising:
placing a first insulating layer adjacent a magnetic field sensor;
positioning a bias layer adjacent said insulating layer; and
laying a second insulating layer adjacent said bias layer.

14. The method of claim 13, wherein said magnetic field sensor comprises:
a base region;
a collector region adjacent said base region;
an emitter region adjacent said base region; and
a barrier region located between said base region and said emitter region.

15. The method of claim 13, wherein said bias layer is positioned between said first insulating layer and said second insulating layer.

16. The method of claim 13, further comprising placing a ferromagnetic layer over said second insulating layer.

17. The method of claim 14, wherein said bias layer is magnetic and is at least three times the thickness of said base region.

18. The method of claim 13, wherein said first insulating layer and said second insulating layer comprise antiferromagnetic materials.
